(19) United States
(12) Patent Application Publication
(10) Pub. No.: US 2005/0035361 A1
(43) Pub. Date: Feb. 17, 2005

(54) Polarized light emitting devices and methods

(76) Inventors: Charles M. Peterson, Sammamish, WA (US); Gene C. Koch, Bayville, NJ (US)

Correspondence Address: Ronald D. Trice;PMB 138, 2101 Crystal Plaza Arcade, Arlington, VA, 22202-4600, US

(21) Appl. No.: 10/641,164

(22) Filed: Aug. 15, 2003

(51) Int. Cl. G02F 1/1335; H01L 33/00

(52) U.S. Cl. 257/98; 349/69; 349/61

(57) ABSTRACT

An organic light emitting device (OLED) including a reflective electrode or reflective backing that emits polarized light, a linear polarizer and/or a band-pass filter may be combined such that substantially all of the light from the OLED is transmitted through the linear polarizer and/or the band-pass filer while ambient light is substantially absorbed. A colored linear polarizer may be to provide the functions of the linear polarizer and the band-pass filer. A light dispersion element also may be included.

### FIELD OF THE INVENTION

The present invention relates generally to a polarized organic light emitting device (OLED) including a polarizer and/or filter, and more particularly, to an OLED with polarized emission including polarizer and/or filter that substantially attenuates ambient light to enhance viewability, and still more particularly, to an OLED with polarized emission including polarizer and/or filter that substantially attenuates ambient light to enhance viewability in combination with a light dispersive element used to alter the viewing field of the image.

### BACKGROUND

Emissive electronic light emitting devices are used in a hundreds of different kinds of devices that are used in a variety of environments. In some of these environments, the images produced by the devices may appear “washed out” when viewed under a high level of ambient illumination such as in direct sunlight. This may occur when illuminating light is reflected by the front surface of the display or is reflected by structures inside of the display such that the perceived contrast of the displayed image is reduced. This is a particular problem with organic light emitting devices (OLEDs) because OLEDs are generally fabricated with a highly reflective cathode and surface interfaces that have a large change in refractive index. The highly reflective cathode and surface interfaces reflect most of the ambient light such that the ambient light washes out the displayed image.

One way this wash out problem has been addressed is to apply a circular polarizer laminated to the front surface that transmits one circular polarization state and absorbs the other circular polarization state. The reflection of ambient light is substantially reduced by the circular polarizer because the light of one circular polarization state is absorbed passing through the polarizer while traveling toward the reflective cathode and on reflection from the metal cathode and other reflective elements the light is converted to the orthogonal polarization state such that it will absorbed by the circular polarizer while traveling away from the reflective elements inside the display. Thus, the image is not washed out by the ambient light because both polarization states of ambient light are absorbed by the circular polarizer. Unfortunately, currently available OLEDs emit both polarization states of light and the circular polarizer absorbs one of the two polarization states of the light produced by the OLED. In order to keep the display luminance at the same level as a device without a circular polarizer, the OLED must be made to emit additional light. This additional light is produced by the application of additional power to the OLED which reduces the life span of the OLED. Additionally, if the OLED is part of a device that is battery-powered, the battery power will be drained at an increased rate (e.g., at least double the rate without the circular polarizer).

Another way the wash out problem has been addressed is to use a transparent OLED structure that includes an extremely thin metal cathode, that is largely transparent, backed by a transparent conductive material that provides sufficient conductivity to efficiently pass current through the OLED. The thin metal cathode and transparent conductive material is then backed by a black, highly light absorbing material. The absorbing material absorbs the majority of ambient light incident on the display such that the wash out problem is obviated. However, since the OLED device is backed by an absorbing material instead of being backed by a reflector, only about half of the light emitted from the emissive layer of the OLED is used to form the image. This light loss occurs because the emissive layer emits light both forwards and backwards. Thus, to keep the display luminance at the same level as a device with a reflective cathode, the OLED must be made to emit additional light which results in the same drawbacks that occur with the inclusion of a circular polarizer.

Similar viewing washout problems result in projection systems wherein images are viewed on a larger screen in a variety of ambient lighting conditions. Unfortunately, the amount of light energy delivered to the viewing screen per unit area is considerable less that direct view display systems. More light energy may be produced by the OLED by increasing the excitation current to the OLED. The increased excitation current substantially shortens the lifetimes of the OLED and creates other problems. One approached to improve the washout problem is to use a beaded screen. Such screens are fabricated by embedding polymer or glass beads in a black matrix. The beads reduce the specular reflections back to the viewer since there are no flat surfaces. The areas between the beads are filled with a black material that absorbs light. Unfortunately, the aperture of a system using such a screen is significantly less than 100% and results in a substantial loss of light emitted by the OLED.

Accordingly, there is a strong need in the art for a way to reduce or eliminate the reflection of ambient light from the display to prevent washing out the display image without losing a substantial portion of the light emitted by the emissive layer of the OLED.

### SUMMARY OF THE INVENTION

100071 An aspect of the invention is to provide a light emitting device including a band-pass filter, a linear polarizer and an organic light emitting device having a light emitter. The linear polarizer is adjacent the band-pass filter and the light emitter emits polarized light.

Another aspect of the invention is to provide a method of providing an image including energizing an organic light emitting device to produce plane polarized light having a predetermined spectrum, linearly polarizing the plane polarized light and absorbing light outside a spectrum of the plane polarized light.

Another aspect of the invention is to provide a light emitting device including a band-pass filter and an organic light emitting device having a light emitter. The light emitter emits light having a narrow spectrum and the band-pass filter transmits light of the narrow spectrum and absorbs light outside the narrow spectrum.

Another aspect of the invention is to provide a method of providing an image including energizing an organic light emitting device to produce polarized light of a narrow spectrum and filtering the reflected light and the polarized light propagating in a direction that allows viewing such that light of outside the narrow spectrum is absorbed.

Another aspect of the invention is to provide a light emitting device including a linear polarizer, a reflector, a band-pass filter and an organic light emitting device having a light emitter. The at least one of the polarizer and the band-pass filter is between the reflector and the light emitter.

Another aspect of the invention is to provide a projection system including a projector including an organic light emitting device having a light emitter, a projection screen including a linear polarizer and projection optics between the projector and the projection screen. The light emitter is selectively energized so as to produce an image that is projected by the projection optics on the projection screen. Brief Description of the Drawings

The invention will be described in detail with reference to the following drawings in which like reference numerals refer to like elements wherein:

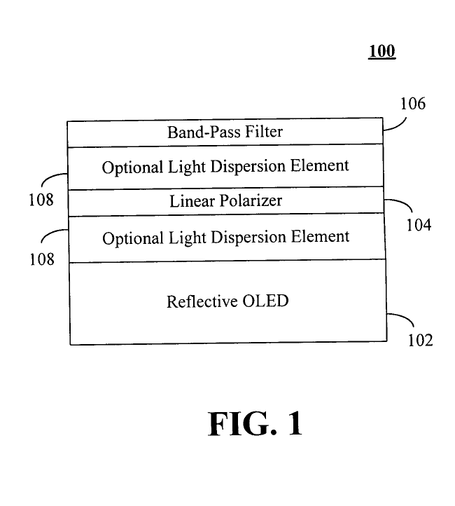

FIG. 1 illustrate an exemplary device having a linear polarizer and a band-pass filter;

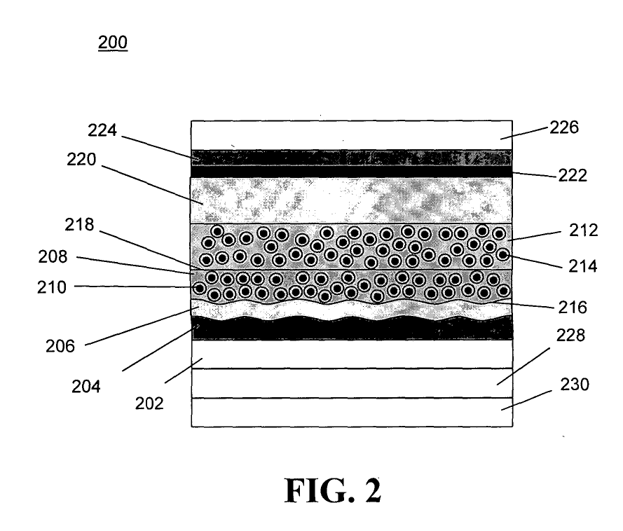

FIG. 2 illustrates an exemplary OLED in combination with a linear polarizer and a band-pass filter;

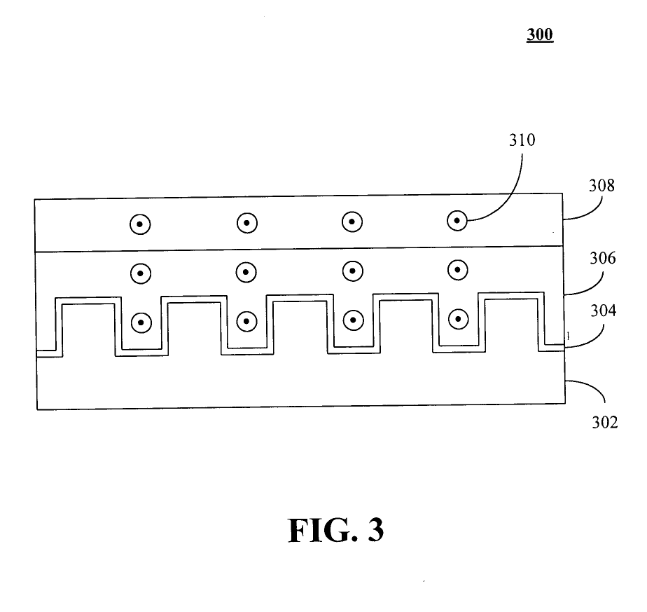

FIG. 3 illustrates emitter molecules being aligned by a surface topology of a first exemplary embodiment;

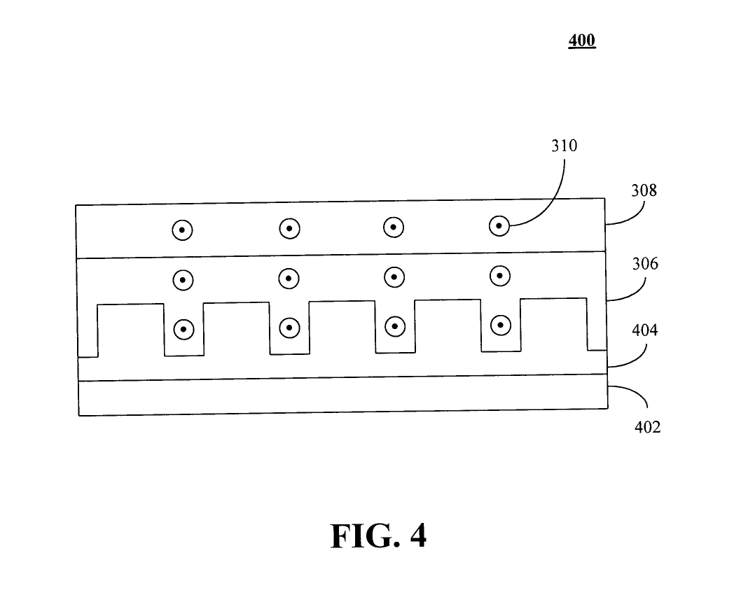

FIG. 4 illustrates emitter molecules being aligned by a surface topology of a second exemplary embodiment;

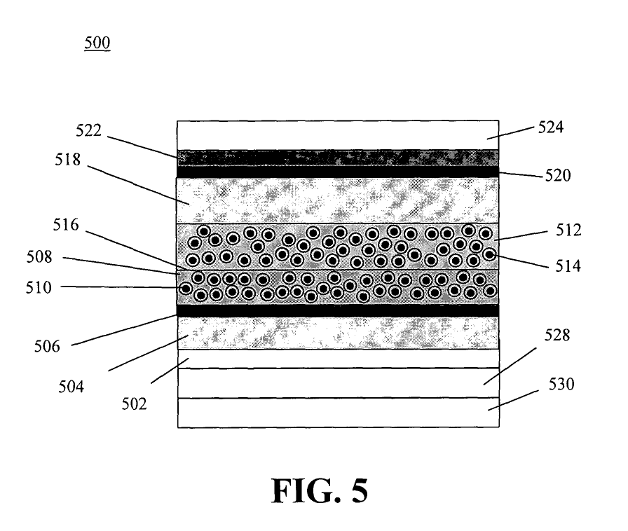

FIG. 5 illustrates another embodiment of the invention where the alignment of liquid crystal is accomplished by with a liquid crystal photoalignment layer;

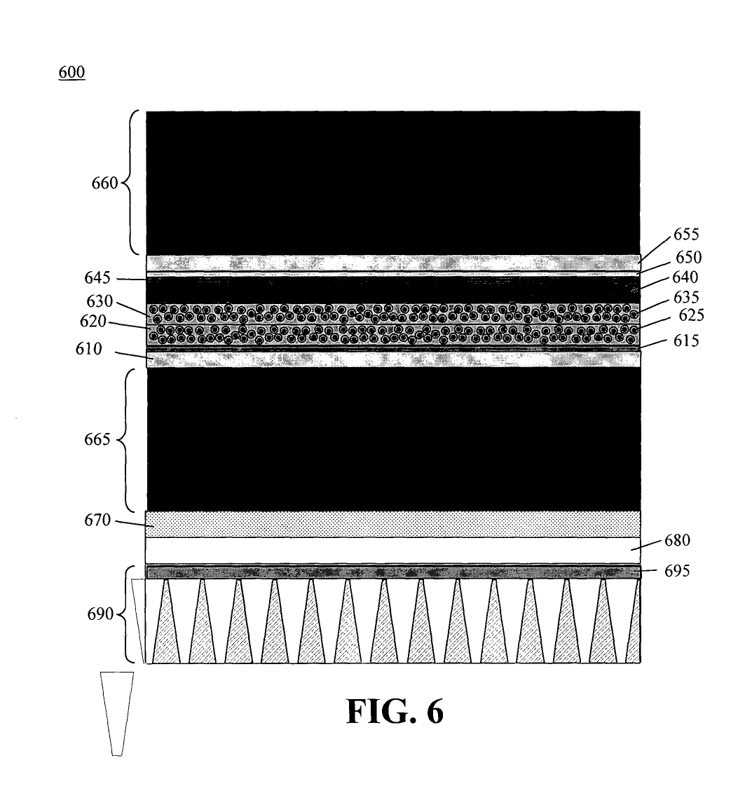

FIG. 6 illustrates another exemplary embodiment of the invention including a feedback enhanced OLED device having viewing properties that are improved with a linear polarizer and band pass filter;

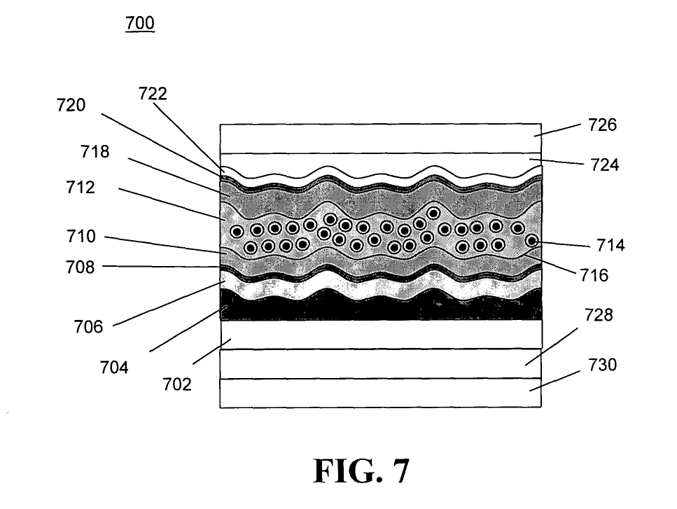

FIG. 7 illustrates another exemplary embodiment including a linear polarizer and a band-pass filter;

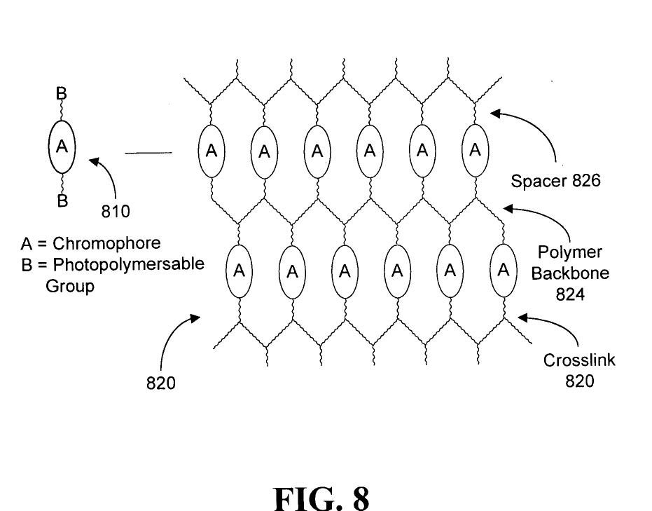

FIG. 8 schematically illustrates the polymerization of reactive monomer to form a crosslinked polymer network;

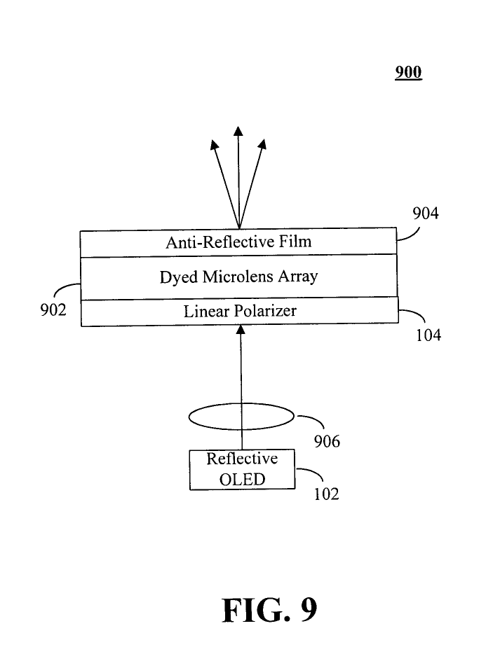

FIG. 9 illustrates rear projection television screen system including a combined light dispersion element and band-pass filter; and

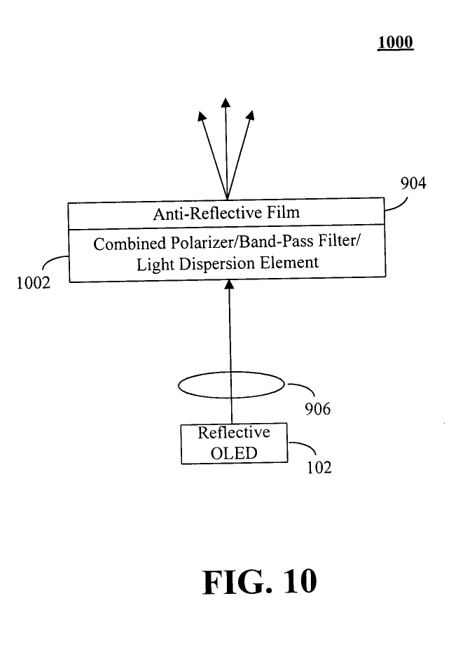

FIG. 10 illustrates rear projection television screen system including a combined polarizer/band-pass filter/light dispersion element.

### DETAILED DESCRIPTION

A polarized organic light emitting device (OLED) including a linear polarizer and/or a band-pass filter may be fabricated that substantially reduces or eliminates unwanted ambient light reflections. FIG. 1 illustrates one exemplary embodiment of such a device 100 that includes a plane polarized light emitting OLED 102 with a reflective electrode or reflective backing, with linear polarizing film 104, and with a band-pass filter 106 laminated or otherwise attached to its front surface. Alternatively, the polarizing film 104 and band-pass filter 106 may be separated from the device 100 by some distance and housed in a structure that maintains the relationship of the polarized emission of the OLED 102 and the polarization axis of the polarizing film 104. Optional anti-reflective or antiglare coatings may be used to reduce surface reflections of the separated elements. The linear polarizing film 104 transmits one linearly polarized state of light and absorbs the other. The polarizing film 104 has its polarizing axis aligned such that the polarized light emitted by the OLED 102 passes through the polarizing film 104 substantially unabsorbed. Light of the orthogonal linear polarization state is substantially absorbed by the polarizing film 104. The band-pass filter 106 is configured such that the spectral emission band or bands emitted by the OLED 102 are transmitted through the band-pass filter 106 substantially unabsorbed while all other wavelengths of light are substantially absorbed by the band-pass filter 106. The polarizing and band pass filtering functions may be fabricated as separate films in the optical stack or may be combined in a single film such as a dyed polarizing film. The direction of the axis of polarization of the emitted light from the emitter layer of the OLED 102 may be selected to provide optimal viewing characteristics to people viewing the display. For example, the polarization axis may be adjusted to be vertical so as to allow viewers to wear polarizing sunglasses.

In another exemplary embodiment of the invention, either the polarizing film 104 or the band-pass filter 106 alone may be attached to the display front surface without the other of the two components. For example, if the OLED 102 is a full-color pixelated display device having red, green and blue emission bands that are spectrally broad, the use of the band-pass filter 106 may not be warranted. However, in this case the use of the linear polarizing film 104 alone still substantially improves the viewability of the display. Conversely, if the OLED 102 is a full-color pixelated display device having red, green and blue emission bands that are spectrally narrow (e.g., few nanometers) the use of the band-pass filter 106 may substantially absorb ambient light thereby improving the viewability of the display. Narrow emission bands may result from the structure used in the device. For example, a feedback element that causes stimulated emission in the light emitter may be used to produce a spectrally narrow emission.

Alternatively, the polarizing film 104 and band-pass filter 106 may be separated from the display by some distance and housed in a structure or positioned such that the relationship of the polarized emission of the OLED 102 and the polarization axis of the polarizing film 104 is maintained. Optionally, anti-reflective or antiglare coatings may be used to reduce surface reflections of the separated elements. Such coatings should not adversely affect the polarization state of the light passing through the coatings (e.g., the polarization state should be maintained).

Most polarizing films are uniaxially birefringent with the extraordinary axis of the birefringence in the same direction as the polarization axis of the film and with a positive value of birefringence. In this case the off-normal viewing characteristics of the OLED/polarizing film combination may be improved by inclusion in the optical stack between the OLED and the polarizer of a uniaxially birefringent film with a positive value of birefringence whose extraordinary axis is normal to the plane of the display.

Additionally, an optional light dispersion element 108 such as a film, optical stack or other device whose function is to alter the angular emission pattern of light emitted from the front surface of the OLED may also be included. When, such a film, optical stack or other device is located between the OLED and the linear polarizing film 104 (e.g., a polarizer), it is configured to substantially preserve the polarization of the light emitted from the OLED. For example, a holographic diffuser film that is polarization preserving may be located between the OLED and the polarizing film 104. When, such a film, optical stack or other device is located on the viewer side of the linear polarizing film, the polarization of the light emitted from the OLED need not be preserved. Instead a low reflectivity and low scattering film, optical stack or other device may be used. For example, the optional light dispersion element 108 for altering the angular viewability of the OLED may be located between the polarizing film 104 and the band-pass filter 106.

Alternatively, the band-pass filter 106 may be combined with the optional light dispersion element 108 to form a single optical element to be used between the viewer and the polarizing film 104. For example, the optional light dispersion element 108 may be dyed to form the band-pass function to the optional element. FIG. 9 illustrates rear projection television screen system 900 including this combined light dispersion element and band-pass filter 902. The combined light dispersion element and band-pass filter 902 may be fabricated from a polycarbonate microlens array (or lenticular array or microlens/lenticular array combination) that that has been dyed. The lenses of the polycarbonate microlens array provide the light dispersion function by refracting light and one or more dyes provide the band-pass filter function by absorbing light not in the spectrum emitted by the OLED 102 (e.g., ambient light). An optional anti-reflective film 904 may be included to further reduce the amount of ambient light reflected by the system 900. Additionally, more ambient light may be absorbed, without addition absorption of the light emitted by the OLED 102, by narrowing the emission spectrum of the OLED 102. The light produced by the OLED 102 is projected by projection optics 906. In such a projection system, the dimensions of the OLED 102 are substantially smaller than that of the screen (e.g. the OLED may be 1.27-5.08 cm (0.5-2.0 inches) while the polarizing film 104 and the combined light dispersion element and band-pass filter 902 may be 127 cm (50 inches) or more.).

Another alternative is to combine the polarizing film 104 and the optional light dispersion element 108 into a single optical element. For example, the polarizing film 104 may be laser ablated to add a light dispersion function to the polarizing film 104.

Yet another alternative is to combine the polarizing film 104 and the band-pass filter 106 into a single optical element. For example, the polarizing film 104 may be dyed to add the band-pass function to the polarizing film 104 or any conventional color polarizer may be used.

Yet another alternative is to combine the polarizing film 104, the band-pass filter 106 and the optional light dispersion element 108 into a single optical element. For example, FIG. 10 illustrates rear projection television screen system 1000 including this combined polarizer/band-pass filter/light dispersion element 1002. The polarizer/band-pass filter/light dispersion element 1002 may be fabricated from one or more polarizing films (e.g., a film that has been impregnated with iodine or another suitable material and then stretched to form the polarizing element of a polarizer. The polarizing element is then laminated between two substrates. The substrates may be made from any suitable material including, for example, triacetyl cellulose (TAC) and cellulose acetate butylate (CAB). Next, ablation, embossing or another suitable method may be used to form the light dispersion features in one of the substrates. Finally, one or more dyes are applied to the substrates and such that the polarizer/band-pass filter/light dispersion element 1002 is completed. An optional anti-reflective film 904 may be included to further reduce the amount of ambient light reflected by the system 1000. Still more ambient light may be absorbed by narrowing the emission spectrum of the OLED 102 and adjusting the absorption spectrum of the band-pass filter 106. This narrower emission spectrum is advantageous because more of the ambient light spectrum may be absorbed without absorbing more of the light emitted by the OLED 102

Organic light emitting devices include a light emitting element or layer. This light emitter may be made from liquid crystalline emitter materials such as calamitic liquid crystals (e.g., nematic liquid crystals and smectic liquid crystals) and other suitable anisotropic emitter materials. The emitted light from such materials may be made plane polarized by uniformly aligning the molecules of the light emitter.

FIG. 2 illustrates an exemplary OLED in combination with a linear polarizer and a band-pass filter. The device 200 of FIG. 2 includes a transparent substrate 202, and a grating structure 204 on which is superimposed a surface relief for aligning liquid crystals, a transparent anode 206 of indium-tin oxide or another suitable material, a hole transport layer 208 of aligned calamitic liquid crystal molecular cores 210 (viewed end on) that are either in a glass phase or are chemically cross-linked together in a glassy polymer or another suitable material, an emitter layer 212 including molecular cores 214 (viewed end on) of a calamitic luminescent material or an aligned, anisotropically emitting luminescent material dissolved in an aligned calamitic host or another suitable material. The calamitic molecular cores 214 in the emitter layer 212 also may be in a glass phase or may be chemically cross-linked together in a glassy polymer. The alignment of the calamitic molecular cores 210 in the hole transport layer 208 may be achieved by their interaction with the surface topology of underlying anode layer 206. The splay and bend elastic constants of the calamitic phase are such that orienting the molecules parallel to the ridges in a first surface 216 is more energetically favorable than alignment in any other direction. The liquid crystalline material in emitter layer 212 is then aligned by interaction between the emitter molecular cores 214 and the electron transport molecular cores 210 at an interface 218. In an alternative embodiment, the hole transport layer 208 may be omitted with the emitter layer 212 performing both the hole transport and emitter functions. In another alternative embodiment the surface topology at the first surface 216 is carried through the electron transport layer 208 such that a second surface 218 has a similar superimposed relief. The alignment of the molecular cores 214 in the emitter layer 212 is then accomplished by interaction with the second surface 218. In this case the hole transport layer 208 may be liquid crystalline or non-liquid crystalline in nature.

An advantage of the device 200 of FIG. 2 is the molecular alignment may be achieved by interaction with the topology of underlying layer or layers instead of through the use of an alignment layer. Thus, the resistive energy losses due to inclusion alignment layers may be avoided.

The device 200 of FIG. 2 also includes an electron transport layer 220, an electron injection layer 222, a reflective metal cathode 224, a hermetic cover 226, and a reflecting layer 226. Alternatively, the device 200 may be inverted in that the cathode 224 may be initially built over the grating structure 204 with molecular alignment or the relief structure from that grating then propagating up through intervening layers (e.g., the electron transport layer 220 and the electron injection layer 222) with the result that an emitter layer 212 with calamitic order is aligned by the relief structure. The final layers of FIG. 2 are a linear polarizer 228 and a band-pass filter 230. The polarizer 228 is aligned so that its transmission axis coincides with the long axes of the molecules 214 in the emitter layer 212 thus enabling polarized light emitted by the device 200 to escape substantially unabsorbed by the polarizer 228.

FIG. 3 illustrates emitter molecules being aligned by a surface topology. The partial device 300 of FIG. 3 includes a liquid crystal alignment structure 302, an electrode 304, a first alignable layer 306 and a second alignable layer 308. The feedback structure 302 may be a photoresist grating with a surface topology. The feedback structure 302 is then coated with indium-tin-oxide electrode to form the electrode 304. The coating thickness is sufficient to provide good electrical contact but thin enough that the electrode 304 has a surface topology similar to that of the feedback structure 302. The topology of the electrode 304 is such that it uniformly aligns the molecules 310 of the first alignable layer 306. The alignment of the first alignable layer 306 then acts to align the molecules 310 of a second alignable layer 308 by a template effect, through intermolecular reactions between the first and second alignable layers 306, 308. The template effect may be used to uniformly align further alignable layers (not shown). Although FIG. 3 illustrates the topology of the electrode 304 as the layer that uniformly aligns the alignable layers, any layer adjacent to an alignable layer may have topology that aligns the emitter. This provides for the topographical alignment of the emitter without the inclusion of a separate alignment layer such that the overall efficiency of the device is improved.

FIG. 4 illustrates emitter molecules being aligned by a surface topology. The partial device 400 of FIG. 4 includes a substrate 402, an electrode 404, a first alignable layer 306 and a second alignable layer 308. The substrate 402 may be any substrate. The substrate is coated with indium-tin-oxide electrode to form the electrode 404. The coating thickness varies such that electrode 404 has a surface topology similar to that of the electrode 404 of FIG. 3. For example, the electrode 404 may be fabricated by depositing indium-tin-oxide in a desired patterned (e.g., depositing a layer of indium-tin-oxide, forming a photoresist mask in the desired pattern, etching the indium-tin-oxide and removing the photoresist mask) and then depositing additional indium-tin-oxide. The additional indium-tin-oxide deposition is sufficiently thick to provide good electrical contact but thin enough that the electrode 404 has a surface topology similar to that of underlying indium-tin-oxide. Alternatively, a layer of indium-tin-oxide may be deposited and then selective portions may be thinned by a timed etch or the like to form the electrode 404. Other methods that produce an electrode 404 of suitable topology may also be used.

The topology of the electrode 404 is such that it uniformly aligns the molecules 310 of the first alignable layer 306. The alignment of the first alignable layer 306 then acts to align the molecules 310 of a second alignable layer 308 by a template effect. The template effect may be used to uniformly align further alignable layers (not shown). Although FIG. 4 illustrates the topology of the electrode 404 as the layer that uniformly aligns the alignable layers, any layer adjacent an alignable layer may have topology that aligns the emitter. This provides for the topological alignment of the emitter without the inclusion of a separate alignment layer such that the overall efficiency of the device is improved.

FIG. 5 illustrates another embodiment of the invention where the alignment of the liquid crystal is accomplished by with a liquid crystal photoalignment layer. Exemplary layers of this type are described in US Patent Applications US2003/0021913 and US 2003/0099785, which are both entitled “Liquid Crystal Alignment Layer” and are incorporated in their entirety by this reference. The device 500 of FIG. 5 includes a transparent substrate 502, a transparent anode 504 fabricated from indium-tin oxide (ITO) or some similar material, a liquid crystal photoalignment layer 506, and a hole transport layer 508 including aligned calamitic liquid crystal molecular cores 510 (viewed end on). The hole transport material may include a liquid crystalline glass phase or it may include liquid crystalline molecules that have been chemically cross-linked. The device 500 further includes an emitter layer 512 including aligned calamitic liquid crystal molecular cores 514 (viewed end on) or an aligned, anisotropically emitting luminescent material dissolved in an aligned calamitic host. The emitter layer 521 also may either include a liquid crystalline glass phase or it may include liquid crystal molecular cores 510 that have been chemically cross-linked. The device 500 also includes an electron transport layer 518, an electron injection layer 520, a reflective metal cathode 522, a hermetic cover 524, a linear polarizer 526, and a triple band-pass filter 530. The polarizer 526 is aligned so that its transmission axis coincides with the long axes of molecules 514 such that polarized light emitted by the device 500 escapes substantially unabsorbed by the polarizer 526.

FIG. 6 illustrates another exemplary embodiment of the invention including a feedback enhanced OLED (FE-OLED) device 600 having viewing properties that are improved with a linear polarizer 670 and band-pass filter 680. The device 600 includes a transparent anode 610 fabricated from indium-tin oxide (ITO) or some other suitable material, a liquid crystal photoalignment layer 615, and a hole transport layer 620 including aligned calamitic liquid crystal molecular cores 625 (viewed end on). The hole transport material may include a liquid crystalline glass phase or it may include liquid crystalline molecules that have been chemically cross-linked. The device 600 further includes an emitter layer 630 including aligned calamitic liquid crystal molecular cores 635 (viewed end on). The calamitic liquid crystal emitter may include an aligned, anisotropically emitting luminescent material dissolved in the aligned calamitic host or another suitable material. Additionally, the emitter may be a single calamitic component, a calamitic liquid crystal mixture, or a calamitic liquid crystal mixture host doped with an anisotropically emitting luminescent material. The emitter layer 630 also may either include a liquid crystalline glass phase or it may be include liquid crystal molecular cores that have been chemically cross-linked. The device 600 also includes an electron transport layer 640, an electron injection layer 645, and a transparent cathode assembly including a thin metal cathode 650 and a transparent, conductive cathode backing fabricated from ITO or some other suitable material. The preceding layers are sandwiched between first and second feedback elements 660, 665. The first and second feedback elements 660, 665 may be layers with a periodically and continuously varying index of refraction. The first feedback element 660 substantially reflects light that is incident on it and is propagating normal to the plane of the device 600. The second feedback element 665 allows some light that is incident on it and is propagating normal to the plane of the device to be transmitted through while the rest is reflected. Light reflected from the first and second feedback structures 660, 665 passes back and forth through the emitter layer 630 several times stimulating further light emission. Light emanating from feedback structure 665 passes through the linear polarizer 670 and the band-pass filter 680 impinging on a rear projection screen 690. The screen 690 may be adhered to the band-pass filter 680 front surface with an adhesive layer 695 or it may be unattached and proximate to the band-pass filter 680. The polarizer 670 is aligned so that its transmission axis coincides with the long axes of molecules 635 such that polarized light emitted by the device 600 passes through the polarizer 670 substantially unabsorbed. Similar to the devices 200, 500 of FIGS. 2 and 5, a substantial portion of ambient illumination that passes through the screen 690 striking the front surface of band-pass filter 680 will be absorbed in the band-pass filter 680 or polarizer 670. Thus the problem of wash out is mitigated. Additional FE_OLED devices useful with the present invention are disclosed in US Patent Application Ser. Nos. 10/434,326 entitled DISPLAY DEVICES USING FEEDBACK ENHANCED EMITTING DIODE”, and 10/319,631 entitled “FEEDBACK ENHANCED LIGHT EMITTING DEVICES”, and 10/431,885 entitled “LIGHTING DEVICES USING FEEDBACK ENHANCED LIGHT EMITTING DIODE AND FEEDBACK ENHANCED LIGHT EMITTING DEVICE” which were all filed on May 8, 2003. The disclosure of each of these applications is incorporated herein by reference.

FIG. 7 illustrates another exemplary embodiment including a linear polarizer and a band-pass filter. The device 700 of FIG. 7 has viewing properties that are improved by the application of the combination of linear polarizers and band pass-filters. The device 700 includes a transparent substrate 702, and a grating structure 704 in which are superimposed surface relief corresponding to both feedback and coupling structures, a transparent anode 706 of, for example, indium-tin oxide, a hole injection layer 708, a hole transport layer 710, an emitter layer 712 including, for example, molecular cores 714 (viewed end on) of a calamitic luminescent material or a anisotropically emitting luminescent material dissolved in a calamitic host. The emitter layer 712 comprises either a glass phase or the calamitic molecular cores are chemically cross-linked together in a glassy polymer. The alignment of the calamitic molecular cores in emitter layer 712 may be achieved by their interaction with the surface topology of underlying hole transmission layer 710. The splay and bend elastic constants of the calamitic phase are such that orienting the molecules parallel to the ridges in surface 716 is more energetically favorable than alignment in any other direction. As a result, the topology resulting from the introduction of the grating 704 may be used to provide multiple functions including: 1. aligning the molecules of the emitter layer 712, 2. providing feedback of light through the emitter layer 712 to stimulate further light emission, and 3. coupling light vertically or substantially vertically out of the device. In addition to the emissive layer 712, one or more of other layers (e.g., the hole transport layer 710, the hole injection layer 708, and the transparent anode 706) may also be made of materials with liquid crystalline order that are homogenously aligned by the topology resulting from grating structure 704. In these cases, the alignment of the emitter layer 712 may be in part due to a template effect resulting from interaction of the emitter material molecular cores with the underlying aligned molecular cores in the hole transmission layer 710.

An advantage of the device 700 of FIG. 7 is the molecular alignment may be achieved by interaction with the topology of underlying layer or layers instead of through the use of an alignment layer. Thus, the resistive energy losses due to inclusion alignment layers may be avoided.

The device 700 of FIG. 7 also includes an electron transport layer 718, an electron injection layer 720, a transmissive cathode structure 722, a planarizing layer 724, and a reflecting layer 726. Alternatively, the device 700 may be inverted in that the cathode structure 722 may be initially built over a grating structure 704 with relief structure from that grating then propagating up through layers the electron transport layer 718 and the electron injection layer 720 with the result that an emitter layer 712 with calamitic liquid crystalline order is aligned by the relief structure. The final layers of FIG. 7 are a linear polarizer 728 and a band-pass filter 730. The polarizer 728 is aligned so that its transmission axis coincides with the long axes of molecules 714 thus enabling polarized light emitted by the device 700 to escape substantially unabsorbed by the polarizer 728.

OLED devices according to the present invention also may include any other suitable structures, layers or elements. Any layers between the emitter and the closest layer having a surface topology used to provide alignment to the emitter are alignable layers. The one or more feedback structures may cause light emitted by the light emitter to be fed back through it along an axis in the plane of the device. The feedback of light thereby promotes the stimulated emission of light in the emitter. Alternatively, OLED devices according to the present invention also may be fabricated including an alignment layer to align the emitter.

The light emitter may be interposed between two electrodes. One of the two electrodes is a cathode and the other of the two electrodes is an anode. The cathode may be fabricated from materials that promote the injection of electrons into the light emitter. The anode may be fabricated from transparent conductive materials that promote injection of holes into the emitter, such as indium-tin oxide. Alternatively, the additional layers may be interposed between the light emitter and the electrodes provided that the resultant topology to results in the alignment of the light emitter molecules. For example, such additional layers may be fabricated from materials that either facilitate injection of charge carriers into the light emitter or transport charge carriers from the site of injection into the desired emissive area in the light emitter. A template effect may be used to uniformly align the light emitter molecules where the layers between the light emitter and the surface topology are alignable. Materials that are alignable include, but are not limited to those having calamitic liquid crystalline phases such as nematic, smectic and hexatic phases and also polymeric materials that have been sheared or otherwise treated so as to align their long molecular axes.

The feedback structures, such as those in FIG. 7, may have a periodic oscillation in refractive index along an axis in the plane of the device. The layer of the device containing this index oscillation is at least partially in the path of the light emitted by the emitter layer and traveling in the plane of the device parallel to the axis along which the index oscillation occurs. The scattering angle for light moving through a volume of material having oscillating refractive index in this parallel configuration is given by the Equation 1:
sin\mathring{m}=(κ−v)/κ (Equation I)
where: \mathring{m} the angle between the normal to the plane of the device and the scattering direction,
K=the wavenumber of the scattered light, and
v=the spatial frequency of the refractive index oscillation.
   By proper selection of K and v, the desired scattering of light from the structure will result. For example, by selecting v=2K, \mathring{M} becomes equal to −90°, and light scattered perpendicular to the (100) planes in the one-dimensional lattice results. This results in the desired feedback structure since part of the light interacting with a structure is reflected straight back while the rest continues straight onward. Such a feedback structure may be described as having a refractive index oscillation with spatial period equal to one-half the wavelength of the emitted light.

The portion of light entrained in the plane of the device by the feedback structure or structures and the portion of the light extracted from the device by the coupling layer are selected to provide a proper balance between the light fed back into the device and the light coupled out of the device. If too much light is coupled out of the device and too little light remains entrained in the plane of the device, there will be insufficient light to support stimulated emission and device radiance will be undesirably low. Conversely, if too little light is coupled out of the device and too much light remains entrained in the plane of the device, the light will pass through absorbing materials and scattering structures in its path so many times that the absorption and other losses will be so great that the overall device radiance will be reduced.

Alternatively, other distributed feedback structures may be used in addition to those described herein as has been described above. Other OLED structures may be substituted for the OLED structures illustrated in the figures. Non-OLED structures may be substituted for the OLED structures illustrated in the figures. The OLED structures may include additional layers such as a hole blocker layer of bathocuproine (2,9-dimethyl-4,7-diphenyl-1,10-phenanthroline) or another suitable material. Blocker layers are discussed in U.S. Pat. Nos. 6,451,415 and 6,097,147.

The gratings herein may be made by different methods and of different materials. For example, the gratings may be fabricated written using electron beam, by multiple (e.g., two) beam interference methods or by or other suitable method. Such gratings may be mass produced by first writing a grating on photoresist or other suitable material and then replicating the grating by an embossing method or another suitable method. The production of multiple copies at a time may be achieved by using a polymer substrate as a master relief structure such as used in used to replicate compact disks and security holograms as used on credit cards and banknotes. The relief structure on the master relief structure is transferred, for example, by electroplating or vacuum deposition, onto a metal shim that may used as a stamp for pressing replicas, or as an injection mould. Alternatively, contact copying onto a further photoresist layer on glass and etching through the photoresist into the glass may be used to fabricate the relief structure in glass. In addition to photoresist and glass, the gratings may be made from polymeric materials such as polycarbonate, polyurethane, or any other suitable material.

With the two beam interference method, collimated beams from a laser of wavelength λ interfere at an angle θ such that λ=2 p sin (θ/2) where p is the desired pitch of the grating. The exposure and development of the photoresist may be varied to control the depth of the relief structure. If two or more gratings of differing pitch are required, the gratings may be superimposed by making two separate exposures on the same photoresist.

The light emitter may be formed from a polymer having a light emitting chromophore. Exemplary chromophores include fluorene, vinylenephenylene, anthracene and perylene. Further exemplary chromophores are described in A. Kraft, A. C. Grimsdale and A. B. Holmes, Angew. Chem. Int. Ed. Eng. [1998], 37, 402.

The reactive mesogen (monomer) of the emitter material typically has a molecular weight of 400 to 2,000. Lower molecular weight monomers are advantageous because their viscosity is lower leading to enhanced spin coating characteristics and shorter annealing times which aids processing. The light emitting polymer typically has a molecular weight of above 4,000, typically 4,000 to 15,000. The emitter polymer typically comprises from 5 to 50, preferably from 10 to 30 monomeric units.

The polymer may be formed by a polymerization process. Such processes may involve the polymerization of reactive mesogens (e.g. in a liquid crystal phase) via photo-polymerization or thermal polymerization of suitable end-groups of the mesogens. Other suitable polymerization processes also may be used. The polymerization process results in cross-linking that produces a cross-linked network.

The polymerization process may be performed in situ after deposition of the reactive mesogens by any suitable deposition process including a spin-coating process and may be formed by photopolymerization of reactive mesogens having photoactive end-groups.

Suitable reactive mesogens have the following general structure:
B-S-A-S-B (general formula 1)
wherein A is at least one of a chromophore, an aromatic molecular core, a heteroaromatic molecular core, or a rigid molecular core with conjugated pi-electron bonds; S is a spacer; and B is an endgroup which is susceptible to radical photopolymerisation.

The polymerization typically results in a light emitting polymer including arrangements of chromophores (e.g. uniaxially aligned) spaced by a crosslinked polymer backbone. FIG. 5 schematically illustrates this process the polymerization of reactive monomer 510 results in the formation of crosslinked polymer network 520 including crosslink 522, polymer backbone 524 and spacer 526 elements.

Suitable spacer (S) groups include unsaturated organic chains, including e.g. flexible aliphatic, amine or ether linkages. The presence of spacer groups aids the solubility and lowers the melting point of the emitter polymer which assists spin coating.

Suitable endgroups are susceptible to photopolymerization (e.g. by a process using UV radiation, generally unpolarized). The polymerization may involve cyclopolymerization where the radical polymerization step results in formation of a cyclic entity.

The polymerization process may involve exposure of a reactive mesogen of general formula 1 to UV radiation to form an initial radical having the general formula as shown below:
B-S-A-S-B.. (general formula 2)
wherein A, S and B are as defined previously and B. is a radicalised endgroup which is capable of reacting with another B endgroup (particularly to form a cyclic entity). The B. radicalised endgroup may include a bound radical such that the polymerization process may be sterically controlled.

Suitable endgroups include dienes such as 1,4, 1,5 and 1,6 dienes. The diene functionalities may be separated by aliphatic linkages, but other inert linkages including but not limited to ether and amine linkages may be employed.

With diene endgroups, the high reactivity of the radicals formed after the photoinitiation step may result in a correspondingly low photodegradation rate as compared to methacrylate endgroups and may result in cyclopolymerization.

This cyclopolymerization may be by a sequential intramolecular and intermolecular propagation: A ring structure is formed first by reaction of the free radical with the second double bond of the diene group. A double ring is obtained by the cyclopolymerization which provides a particularly rigid backbone (the rigid backbone minimizes or eliminates shrinkage). The reaction is in general, sterically controlled.

Exemplary reactive mesogens may have the general formula: 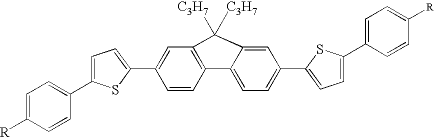
wherein R has the general formula: X-S2-Y-Z
and wherein
X=O, CH₂ or NH and preferably X=O;
S2=linear or branched alkyl or alkenyl chain optionally including a heteroatom (e.g. O,S or NH);
Y=O, CO₂ or S; and
Z=a diene (end-group).

For example, R may be selected from:

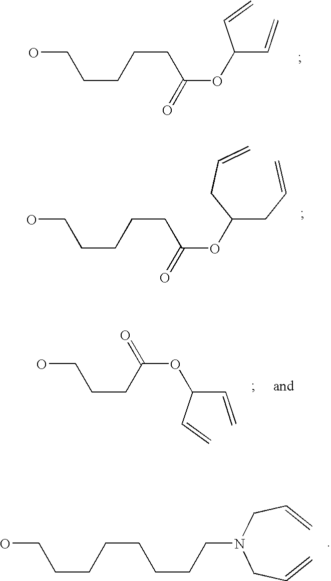

The compounds with the above Rs exhibit a nematic phase with a clearing point (N-I) between 79 and 120° C.

The photopolymerization process may be conducted at room temperature, thereby reducing or minimizing any possible thermal degradation of the reactive mesogen or polymer entities. Additionally, subsequent sub-pixellation of the formed polymer by lithographic means may be performed with photopolymerization.

Further steps may be conducted prior to the polymerization process including doping of the reactive mesogen. The dopant may in aspects include a further reactive monomer capable of co-polymerization with the reactive mesogen. This monomer may be used to provide the other alignable layers. Further information on how to prepare these layers may be found in Published US Patent application no. 2003/0027017.

Any OLED that includes a reflective electrode or reflective backing and emits polarized light may be used as the OLED in the present invention. Any OLED without a reflective electrode or reflective backing that emits polarized light may be used as the OLED in the present invention.

The films, layers and the like having certain functions may have non-film, non-layer equivalent substituted therefor. For example, a wire grid polarizer may be substituted for a polarizing film or layer.

The present invention may be applied to direct view devices and systems, rear projection systems, front projections systems, other viewed devices and systems, 1:1 projected displays where the image is not substantially magnified, displays systems where the image is magnified and viewed on a screen as both front and rear projections systems, systems where the image is magnified and viewed directly through optics without an additional viewing screen, segmented displays and devices, single pixel displays and devices, and devices and systems that are not viewed.

Although several embodiments of the present invention and its advantages have been described in detail, it should be understood that changes, substitutions, transformations, modifications, variations, permutations and alterations may be made therein without departing from the teachings of the present invention, the spirit and the scope of the invention being set forth by the appended claims.

1. A light emitting device comprising:
a band-pass filter;
a linear polarizer; and
an organic light emitting device having a light emitter,
wherein the linear polarizer is adjacent the band-pass filter, and
wherein the light emitter emits polarized light.

2. The device of claim 1,
wherein the polarized light has a predetermined spectrum, and
wherein the band-pass filter transmits light of the predetermined spectrum and absorbs light outside the predetermined spectrum.

3. The device of claim 2, wherein the band-pass filter and the linear polarizer are formed separately.

4. The device of claim 2, wherein the band-pass filter and the linear polarizer are a single film.

5. The device of claim 4, wherein the single film is a dyed polarizing film.

6. The device of claim 2, further comprising an element that alters an angular emission pattern of light emitted from a front surface of the organic light emitting device.

7. The device of claim 6, wherein the element, the band-pass filter and the linear polarizer are a single film.

8. The device of claim 1, wherein the polarized light includes red, green and blue components.

9. The device of claim 1, further comprising an element that alters an angular emission pattern of light emitted from a front surface of the organic light emitting device.

10. The device of claim 9,
wherein the element is a holographic diffuser film that is polarization preserving and
wherein the holographic diffuser film is between the organic light emitting device and the linear polarizer.

11. The device of claim 9,
wherein the element is a holographic diffuser film that has low reflectivity and low scattering; and
wherein the linear polarizer is between the organic light emitting device and the holographic diffuser film.

12. The device of claim 1, wherein the light emitter is a liquid crystal emitter.

13. The device of claim 12, wherein the light emitter is a nematic liquid crystal emitter.

14. The device of claim 1, wherein the polarized light is plane polarized light.

15. The device of claim 1, further comprising at least one anti-reflective film.

16. The device of claim 1, further comprising an optical compensation film.

17. The device of claim 1, further comprising a reflector, wherein the light emitter is between the reflector and the linear polarizer.

18. A rear projection system comprising the light emitting device of claim 1.

19. A method of providing an image comprising:
energizing an organic light emitting device to produce plane polarized light having a predetermined spectrum;
linearly polarizing the plane polarized light; and
absorbing light outside a spectrum of the plane polarized light.

20. The method of claim 19, wherein the linearly polarizing and absorbing substantially attenuates light not emitted from the organic light emitting device.

21. The method of claim 20, wherein attenuated light includes ambient light.

22. The method of claim 18, further comprising:
reflecting the plane polarizing light propagating away from a direction that allows viewing such that the reflected light is propagating in a direction that allows viewing.

23. A light emitting device comprising:
a band-pass filter; and
an organic light emitting device having a light emitter,
wherein the light emitter emits light having a narrow spectrum,
wherein the band-pass filter transmits light of the narrow spectrum and absorbs light outside the narrow spectrum.

24. The device of claim 23, further comprising a linear polarizer.

25. The device of claim 24, wherein the band-pass filter and the linear polarizer are formed separately.

26. The device of claim 24, wherein the band-pass filter and the linear polarizer are a single film.

27. The device of claim 26, wherein the single film is a dyed polarizing film.

28. The device of claim 24, further comprising an element that alters an angular emission pattern of light emitted from a front surface of the organic light emitting device.

29. The device of claim 28, wherein the element, the band-pass filter and the linear polarizer are a single film.

30. The device of claim 23, wherein the narrow spectrum includes red, green and blue components.

31. The device of claim 30, wherein each of the red, green and blue components have a bandwidth of a few nm.

32. The device of claim 30, wherein the narrow bandwidth results from feedback that causes stimulated emission in the light emitter.

33. The device of claim 23, further comprising an element that alters an angular emission pattern of light emitted from a front surface of the organic light emitting device.

34. The device of claim 33, wherein the element is a holographic diffuser film that is polarization preserving and the holographic diffuser film is between the organic light emitting device and the linear polarizer.

35. The device of claim 33,
wherein the element is a holographic diffuser film that has low reflectivity and low scattering; and
wherein the linear polarizer is between the organic light emitting device and the holographic diffuser film.

36. The device of claim 23, wherein the light emitter is a liquid crystal emitter.

37. The device of claim 36, wherein the light emitter is a nematic liquid crystal emitter.

38. The device of claim 23, wherein the light is plane polarized light.

39. The device of claim 23, further comprising a reflector, wherein the light emitter is between the reflector and the band-pass filter.

40. The device of claim 39, further comprising at least one anti-reflective film.

41. The device of claim 23, further comprising an optical compensation film.

42. A rear projection system comprising the light emitting device of claim 23.

43. A method of providing an image comprising:
energizing an organic light emitting device to produce polarized light of a narrow spectrum; and
filtering the reflected light and the polarized light propagating in a direction that allows viewing such that light of outside the narrow spectrum is absorbed.

44. A light emitting device comprising:
a linear polarizer;
a reflector;
a band-pass filter; and
an organic light emitting device having a light emitter,
wherein at least one of the polarizer and the band-pass filter is between the reflector and the light emitter.

45. A projection system comprising:
a projector including an organic light emitting device having a light emitter;
a projection screen including a linear polarizer; and
projection optics between the projector and the projection screen,
wherein the light emitter is selectively energized so as to produce an image that is projected by the projection optics on the projection screen.

46. The system of claim 45, wherein the projection screen further comprises a band-pass filter.

47. The system of claim 46, wherein the projection screen further comprises an element that alters an angular emission pattern of light.

48. The system of claim 45, wherein the projection screen further comprises an element that alters an angular emission pattern of light.

49. The system of claim 48, wherein the element comprises at least one of a dyed micro-optic film and a dyed lenticular array.

50. The system of claim 45, wherein the projection screen further comprises an optical compensation film.

51. The system of claim 45, wherein the light emitter has a narrow emission spectrum.

52. The system of claim 45, wherein the projection screen is a rear projection screen.
